(19) United States
(12) Patent Application Publication
(10) Pub. No.: US 2025/0169339 A1
(43) Pub. Date: May 22, 2025

(54) DISPLAY PANEL, DISPLAY MODULE AND DISPLAY DEVICE

(71) Applicant: Yungu (Gu’an) Technology Co., Ltd., Langfang (CN)

(72) Inventors: Xiaowei XU, Langfang (CN); Lixiang ZHANG, Langfang (CN); Xiaokang ZHOU, Langfang (CN)

(73) Assignee: Yungu (Gu’an) Technology Co., Ltd., Langfang (CN)

(21) Appl. No.: 18/951,688

(22) Filed: Nov. 19, 2024

(30) Foreign Application Priority Data
Nov. 21, 2023 (CN) 202311560021.4

(51) Int. Cl. H10K 59/80; H10K 39/34

(52) U.S. Cl. CPC H10K 59/879; H10K 39/34

(57) ABSTRACT

Disclosed are a display panel, a display module and a display device. The display panel includes: a plurality of pixels and a light guiding layer provided above the pixels with a plurality of light guiding structures. The pixel includes a photosensitive unit and a plurality of light-emitting units. The light-emitting unit includes a first light-emitting unit configured to emit a first visible light, and the photosensitive unit is configured to detect the first visible light. The first visible light is received by the corresponding photosensitive unit through the corresponding light guiding structure. The first light-emitting unit has a first center line, the photosensitive unit has a second center line, the light guiding structure has a third center line. A first shortest distance between the second center line and the first center line is greater than a second shortest distance between the third center line and the first center line.

### CROSS-REFERENCE TO RELATED APPLICATIONS

This application claims priority to Chinese Patent Application No. 202311560021.4, filed on Nov. 21, 2023, which is hereby incorporated by reference in its entirety.

### TECHNICAL FIELD

The present disclosure relates to the field of display technologies, and in particular, to a display panel, a display module and a display device.

### BACKGROUND

Currently, image recognition has become one of standard applications equipped on a display terminal product. However, there is still a problem of low signal-to-noise ratio in image recognition performance of the display terminal product in the prior art.

### SUMMARY

To address a technical problem mentioned above, the present application is proposed. Embodiments of the present disclosure provide a display panel, a display module, and a display device.

In a first aspect, an embodiment of the present disclosure provides a display panel. The display panel includes: a plurality of pixels, at least part of the plurality of pixels including a photosensitive unit and a plurality of light-emitting units, the plurality of light-emitting units including a first light-emitting unit, the first light-emitting unit configured to emit at least a first visible light, and the photosensitive unit configured to detect the first visible light; and
a light guiding layer provided above the plurality of pixels, including a plurality of light guiding structures, the first visible light emitted by the first light-emitting unit being received by a corresponding photosensitive unit through a corresponding light guiding structure
where in one pixel, the first light-emitting unit has a first center line, the first center line is a straight line passing through a center of the first light-emitting unit in a vertical direction, the photosensitive unit has a second center line, the second center line is a straight line passing through a center of the photosensitive unit in the vertical direction, and the light guiding structure corresponding to the photosensitive unit has a third center line, the third center line is a straight line passing through a center of the light guiding structure corresponding to the photosensitive unit in the vertical direction, a first shortest distance is a shortest distance between the second center line and the first center line, a second shortest distance is a shortest distance between the third center line and the first center line, and the first shortest distance is greater than the second shortest distance.

In a second aspect, an embodiment of the present disclosure provides a display module. The display module includes: a display panel, including a plurality of pixels, at least part of the plurality of pixels including a photosensitive unit and a plurality of light-emitting units, the plurality of light-emitting units including a first light-emitting unit, the first light-emitting unit configured to emit at least a first visible light, and the photosensitive unit configured to detect the first visible light; and
a light guiding layer provided above the plurality of pixels, including a plurality of light guiding structures, the first visible light emitted by the first light-emitting unit being received by a corresponding photosensitive unit through a corresponding light guiding structure,
where in one pixel, the first light-emitting unit has a first center line, the first center line is a straight line passing through a center of the first light-emitting unit in a vertical direction, the photosensitive unit has a second center line, the second center line is a straight line passing through a center of the photosensitive unit in the vertical direction, the light guiding structure corresponding to the photosensitive unit has a third center line, the third center line is a straight line passing through a center of the light guiding structure corresponding to the photosensitive unit in the vertical direction, a first shortest distance is a shortest distance between the second center line and the first center line, a second shortest distance is a shortest distance between the third center line and the first center line, and the first shortest distance is greater than the second shortest distance.

In a third aspect, an embodiment of the present disclosure provides a display device. The display device includes: a display panel according to any one of embodiments mentioned above; or a display module according to any one of embodiments mentioned above.

### BRIEF DESCRIPTION OF THE DRAWINGS

Through a more detailed description of embodiments of the present disclosure with reference to the drawings, the above-mentioned and other objectives, features, and advantages of the present disclosure would become more apparent. The drawings are used for providing further understanding of the embodiments of the present disclosure and constitute a part of the specification, explain the present disclosure together with the embodiments of the present disclosure, and do not constitute a limitation to the present disclosure. In the drawings, the same reference numerals generally represent the same components or steps.

FIG. 1 is a cross-sectional view of a structure of a display module in relative technologies.

FIG. 2 is a top view of a structure of a display panel according to an embodiment of the present disclosure.

FIG. 3a is a cross-sectional view of the structure shown in FIG. 2 along A1A2.

FIG. 3b is a schematic diagram of a local part of the structure shown in FIG. 3a.

FIG. 4a is a locally enlarged diagram of a display panel according to an embodiment of the present disclosure in a top-down view.

FIG. 4b is a locally enlarged diagram of a display panel according to an another embodiment of the present disclosure in a top-down view.

FIG. 4c is a locally enlarged diagram of a display panel according to still another embodiment of the present disclosure in a top-down view.

FIG. 4d is a locally enlarged diagram of a display panel according to yet still another embodiment of the present disclosure in a top-down view.

FIG. 4e is a locally enlarged diagram of a display panel according to yet still another embodiment of the present disclosure in a top-down view.

FIG. 5 is a schematic diagram of correspondence between an output angle and light intensity of a light-emitting unit according to an embodiment of the present disclosure.

FIG. 6 is a cross-sectional view of a structure shown in FIG. 2 along A1A3.

FIG. 7 is a local view of the structure shown in FIG. 6.

FIG. 8 is a local cross-sectional view of a structure of a display panel according to another embodiment of the present disclosure.

FIG. 9 is a local cross-sectional view of a structure of a display panel according to still another embodiment of the present disclosure.

FIG. 10 is a local cross-sectional view of a structure of a display panel according to yet still another embodiment of the present disclosure.

FIG. 11 is a local cross-sectional view of a structure of a display panel according to yet still another embodiment of the present disclosure.

FIG. 12 is a local cross-sectional view of a structure of a display panel according to yet still another embodiment of the present disclosure.

FIG. 13 is a schematic diagram of a structure of a display panel according to yet still another embodiment of the present disclosure.

FIG. 14 is a cross-sectional view of a structure of a display module according to an embodiment of the present disclosure.

FIG. 15 is a local view of a structure of the display module shown in FIG. 14.

FIG. 16 is a local view of another structure of the display module shown in FIG. 14.

FIG. 17 is a local view of still another structure of the display module shown in FIG. 14

FIG. 18 is a schematic diagram of a structure of a display module according to another embodiment of the present disclosure.

FIG. 19 is a schematic diagram of a structure of a display module according to still another embodiment of the present disclosure.

FIG. 20 is a schematic diagram of a structure of a display device according to an embodiment of the present disclosure.

### DETAILED DESCRIPTION OF THE EMBODIMENTS

Image recognition is widely used in display products, and an image sensor is accordingly developed. As a type of the image sensor, fingerprint sensors provide users with great convenience in scenarios such as device unlocking and mobile payments. Current fingerprint recognition methods include optical fingerprint recognition, ultrasonic fingerprint recognition, and capacitive fingerprint recognition, among which optical fingerprint recognition is widely adopted due to its significant advantages in power consumption, response speed, and cost.

In some implementations, fingerprint recognition is achieved by attaching an independent optical fingerprint recognition sensor to the back of the screen. However, this approach places high demands on transmittance of a display panel of a display product. Unfortunately, due to integration of various functions in a display product, such as Color filter On Encapsulation (COE) technology (also known as “no polarizer technology”), Fanout in Active Area (FIAA) technology, and Low Temperature Polycrystalline Oxide (LTPO) technology, the transmittance of the display panel has been significantly reduced, putting formard higher requirement for response time, a false recognition rate, and a rejection rate of fingerprint recognition.

In view of this, a new type of on-screen optical fingerprint recognition technology has been proposed. In this technology, an optical fingerprint recognition device is integrated into a display panel, without increasing a thickness of the display panel, achieving large-area fingerprint recognition. However, this technology still faces many technical problems currently, one of which is a low signal-to-noise ratio (SNR), which refers to the ratio of the strength of the useful signal to the strength of the interference signal received by the device.

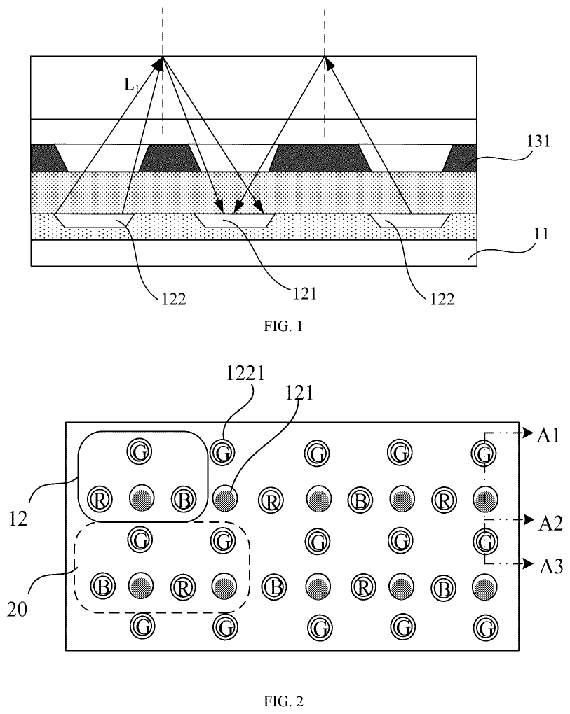

FIG. 1 is a cross-sectional view of a structure of a display module in relative technologies. As shown in FIG. 1, the display module includes a substrate 11, a photosensitive unit 121 and a light-emitting unit 122 located on the substrate 11. The photosensitive unit 121 and the light-emitting unit 122 are arranged in a same layer. The display module further includes a light absorbing structure 131 stacked on a side, away from the substrate 11, of the photosensitive unit 121 and the light-emitting unit 122. A plurality of light outlet openings are provided in the light absorbing structure 131, and the photosensitive unit 121 and the light-emitting unit 122 correspond to the light outlet openings respectively. In a thickness direction of the substrate 11, the light outlet opening is located above the photosensitive unit 121 or the light-emitting unit 122. In this implementation, a center of the light-emitting unit 122 coincides with a center of the corresponding light outlet opening, and a center of the photosensitive unit 121 coincides with a center of the corresponding light outlet opening.

As shown in FIG. 1, each photosensitive unit 121 is surrounded by a plurality of light-emitting units 122 in an adjacent manner. For example, there are two light-emitting units 122 arranged around the photosensitive unit 121, which are located on opposite sides of the photosensitive unit 121. When the photosensitive unit 121 is configured to detect a first visible light L₁ emitted by one of the light-emitting units 122, on the one hand, there may be a problem of insufficient first visible light L₁ emitted by aforementioned light-emitting unit 122 and received by the photosensitive unit 121; on the other hand, the first visible light emitted by another light-emitting unit 122 may be also collected by the photosensitive unit 121 as noise. These two reasons lead to a low signal-to-noise ratio for fingerprint recognition by the display module.

In view of this, embodiments of the present disclosure provide a display panel. By adjusting a relative position between a light outlet opening and a photosensitive unit, and a relative position between the light outlet opening and a light-emitting unit, the signal intensity of useful signals collected by the photosensitive unit increases, so that a signal-to-noise ratio is improved. In other implementation, noise collected by the photosensitive unit may also be reduced, further improving the signal-to-noise ratio.

In the following, a clear and comprehensive description of technical solutions in the embodiments with reference to the drawings will be provided. Obviously, the embodiments described are only a part of the embodiments of the present disclosure, not all of them. Based on the embodiments in the present disclosure, all other embodiments obtained by those skilled in the art without creative efforts belong to the protection scope of the present disclosure.

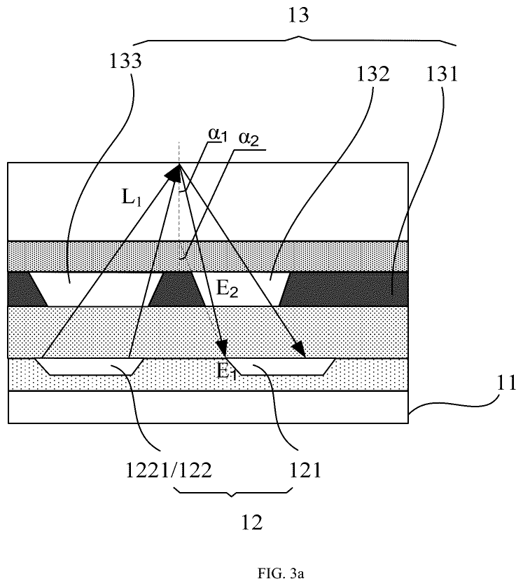

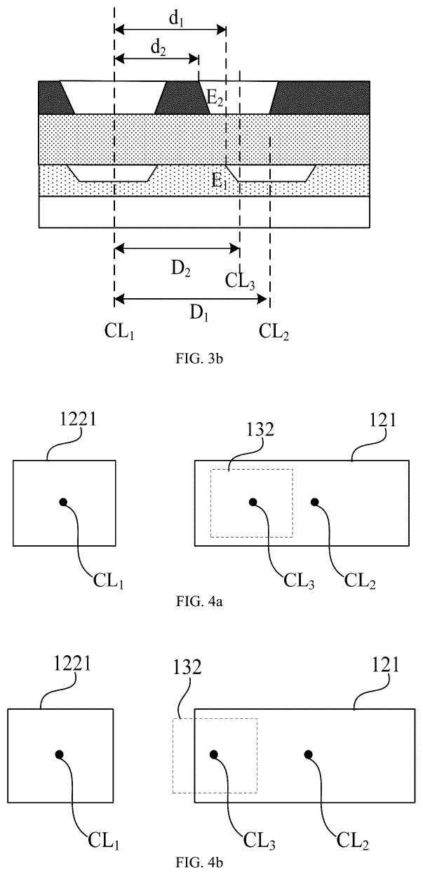

FIG. 2 is a top view of a structure of a display panel according to an embodiment of the present disclosure. FIG. 3a is a cross-sectional view of the structure shown in FIG. 2 along A1A2. As shown in FIG. 2 and FIG. 3a, the display panel includes a plurality of pixels 12 and a light guiding layer 13.

At least part of the plurality of pixels 12 includes a photosensitive unit 121 and a plurality of light-emitting units 122. For example, when the display panel is configured to be a half-screen fingerprint recognition display panel, some of the plurality of pixels 12 include a photosensitive unit 121 and a plurality of light-emitting units 122, while the remaining pixels 12 only include a plurality of light-emitting units 122. For another example, when the display panel is configured to be a full-screen fingerprint recognition display panel, each of the plurality of pixels 12 includes a photosensitive unit 121 and a plurality of light-emitting units 122.

The plurality of light-emitting units 122 within one pixel 12 may be configured to emit visible light of different colors. For example, as shown in FIG. 2, the pixel 12 includes three light-emitting units 122, which emit visible light of different colors. Exemplarily, red light, green light, and blue light are emitted by three light-emitting units 122 respectively. In other embodiments, the pixel 12 may further include a light-emitting unit that emits white light.

As shown in FIG. 2, the display panel includes a repeating unit 20, and the repeating unit 20 may be used in a design process of pixel layout to arrange copied graphics of the repeating unit 20 in rows and columns to obtain a pixel layout of the display panel. Exemplarily, as shown in FIG. 2, in this embodiment, adjacent pixels 12 share a common light-emitting unit 122 in a direction of pixel rows. In a case where a pixel 12 includes three light-emitting units 122 and one photosensitive unit 121, the three light-emitting units 122 and one photosensitive unit 121 in a pixel 12, as well as one light-emitting unit 122 and one photosensitive unit 121 in another adjacent pixel 12, constitute a repeating unit 20.

In one pixel 12, the plurality of light-emitting units 122 include a first light-emitting unit 1221, configured to emit at least a first visible light L₁, and the photosensitive unit 121, configured to detect the first visible light L₁.

The light guiding layer 13 is located above the plurality of pixels 12 and includes a plurality of light guiding structures 132. The light guiding layer 13 is a layer used for guiding light emitted by the light-emitting unit. The first visible light L₁ emitted by the first light-emitting unit 1221 is received by the corresponding photosensitive unit 121 through the corresponding light guiding structure 132. The light guiding structure 132 is used for providing a light guiding path to direct the first visible light L₁ emitted by the first light-emitting unit 1221 to the photosensitive unit 121. For example, in some implementation, the light guiding layer 13 includes a light absorbing structure 131, and a plurality of light outlet openings are defined by the light absorbing structure 131. The light guiding structure 132 is a color resistance structure located inside the light outlet opening or a structure made of transparent material.

FIG. 3b is a local view of a structure shown in FIG. 3a. As shown in FIG. 3a and FIG. 3b, in one pixel 12, the first light-emitting unit 1221 has a first center line CL₁, the first center line CL₁ is a straight line passing through a center of the first light-emitting unit 1221 in a vertical direction, the photosensitive unit 121 has a second center line CL₂, the second center line CL₂ is a straight line passing through a center of the photosensitive 121 unit in a vertical direction, and the light guiding structure 132 corresponding to the photosensitive unit 121 has a third center line CL₃, the third center line CL₃ is a straight line passing through a center of the light guiding structure 132 corresponding to the photosensitive unit 121 in a vertical direction. A first shortest distance D₁ is a shortest distance between the second center line CL₂ and the first center line CL₁, and a second shortest distance D₂ is a shortest distance between the third center line CL₃ and the first center line CL₁. The first shortest distance D₁ is greater than the second shortest distance D₂.

In one pixel 12, the first center line CL₁ of the first light-emitting unit 1221, the second center line CL₂ of the photosensitive unit 121, and the third center line CL₃ of the light guiding structure 132 corresponding to the photosensitive unit 121 are parallel to each other. For example, the display panel further includes a substrate 11. The first center line CL₁ of the first light-emitting unit 1221, the second center line CL₂ of the photosensitive unit 121, and the third center line CL₃ of the light guiding structure 132 corresponding to the photosensitive unit 121 are all perpendicular to the substrate 11. The first shortest distance D₁ between the second center line CL₂ and the first center line CL₁ refers to a perpendicular line drawn from any point on the second center line CL₂ to the first center line CL₁, and a length of this perpendicular line is the first shortest distance D₁. The second shortest distance D₂ between the third center line CL₃ and the first center line CL₁ refers to a perpendicular line drawn from any point on the third center line CL₃ to the first center line CL₁, and a length of this perpendicular line is the second shortest distance D₂.

According to the display panel provided in this embodiment, in one pixel 12, the first shortest distance D₁ is configured to be greater than the second shortest distance D₂, that is, in a thickness direction of the substrate 11, an orthographic projection of the photosensitive unit 121 on the substrate 11 does not coincides with an orthographic projection of the light guiding structure 132 on the substrate 11. The third center line CL₃ of the light guiding structure 132 is closer to the first light-emitting unit 1221 than the second center line CL₂ of the photosensitive unit 121.

In a case where the third center line CL₃ of the light guiding structure 132 is closer to the first light-emitting unit 1221 than the second center line CL₂ of the photosensitive unit 121, a positional relationship between the light guiding structure 132 and the photosensitive unit 121 may be adjusted appropriately. In the following, several exemplary implementations will be provided.

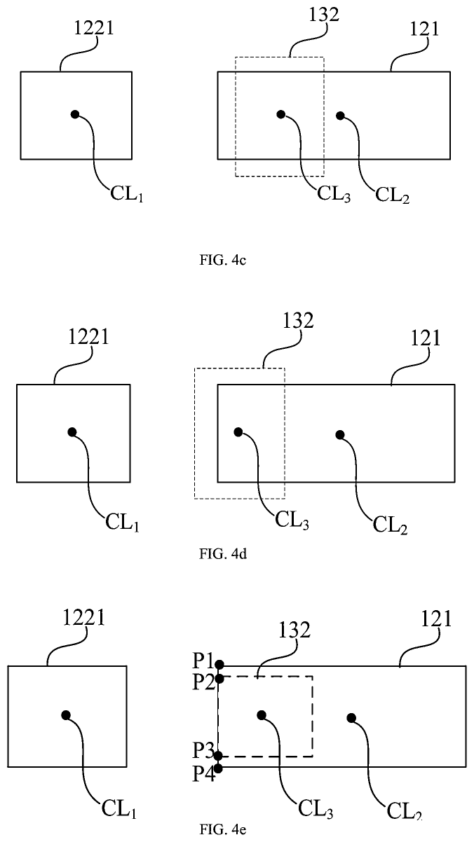

FIG. 4a is a locally enlarged diagram of a display panel according to an embodiment of the present disclosure in a top-down view. As shown in FIG. 4a, in one pixel 12, an orthographic projection of the light guiding structure 132 on the substrate 11 is located within an orthographic projection of the photosensitive unit 121 on the substrate 11. In this case, an area of an opening of the light guiding structure 132 is less than an area of an opening of the photosensitive unit 121.

A shape of the opening of any one of the light guiding structure 132, the photosensitive unit 121, and the light-emitting unit 122 may be circular or polygonal, such as rectangular, diamond, and so on.

FIG. 4b is a locally enlarged diagram of a display panel according to another embodiment of the present disclosure in a top-down view. By comparing FIG. 4a and FIG. 4b, it can be seen that a difference lies in that in this embodiment, within one pixel 12, part of an orthographic projection of the light guiding structure 132 on the substrate 11 is located within the orthographic projection of the photosensitive unit 121 on the substrate 11, while the remaining part is located outside the orthographic projection of the photosensitive unit 121 on the substrate 11. That is, the orthographic projection of the light guiding structure 132 on the substrate 11 partially overlaps with the orthographic projection of the photosensitive unit 121 on the substrate 11. Moreover, the remaining part of the orthographic projection of the light guiding structure 132 that does not overlap with the orthographic projection of the photosensitive unit 121 is located on a side, close to the first light-emitting unit 1221, of the third center line CL₃.

In this embodiment, as shown in FIG. 4b, an area of an opening of the light guiding structure 132 is less than an area of an opening of the photosensitive unit 121.

FIG. 4c is a locally enlarged diagram of a display panel according to still another embodiment of the present disclosure in a top-down view. By comparing FIG. 4c and FIG. 4b, it can be seen that a difference lies in that in this embodiment, part of the orthographic projection of the light guiding structure 132 that does not overlap with the orthographic projection of the photosensitive unit 121 is located on opposite sides of the third center line CL₃, and the opposite sides refer to two sides of a virtual line connecting the first center line CL₁ and the second center line CL₂.

FIG. 4d is a locally enlarged diagram of a display panel according to yet still another embodiment of the present disclosure in a top-down view. By comparing FIG. 4d, FIG. 4b and FIG. 4c, it can be seen that FIG. 4d may be considered as a combination of FIG. 4b and FIG. 4c. Specifically, part of the orthographic projection of the light guiding structure 132 that does not overlap with the orthographic projection of the photosensitive unit 121 is located on the opposite sides of the third center line CL₃ and on a side, close to the first light-emitting unit 1221, of the third center line CL₃. Therein, the opposite sides refer to two sides of a virtual line connecting the first center line CL₁ and the second center line CL₂.

FIG. 4e is a locally enlarged diagram of a display panel according to yet still another embodiment of the present disclosure in a top-down view. By comparing FIG. 4e and FIG. 4a, it can be seen that a difference lies in that in this embodiment, an orthographic projection of an edge line of an opening of the light guiding structure 132 on the substrate 11 partially overlaps with an orthographic projection of an edge line of an opening of the photosensitive unit 121 on the substrate 11. For example, an orthographic projection of an edge line, closer to the first center line CL₁, of the opening of the light guiding structure 132 on the substrate 11 partially overlaps with an orthographic projection of an edge line, closer to the first center line CL₁, of the opening of the photosensitive unit 121 on the substrate 11. Exemplarily, as shown in FIG. 4e, an edge line P1P4 partially overlaps with an edge line P2P3. Therein, the edge line P2P3 is the orthographic projection of the edge line, closer to the first center line CL₁, of the opening of the light guiding structure 132 on the substrate 11. And the edge line P1P4 is the orthographic projection of the edge line, closer to the first center line CL₁, of the opening of the photosensitive unit 121 on the substrate 11.

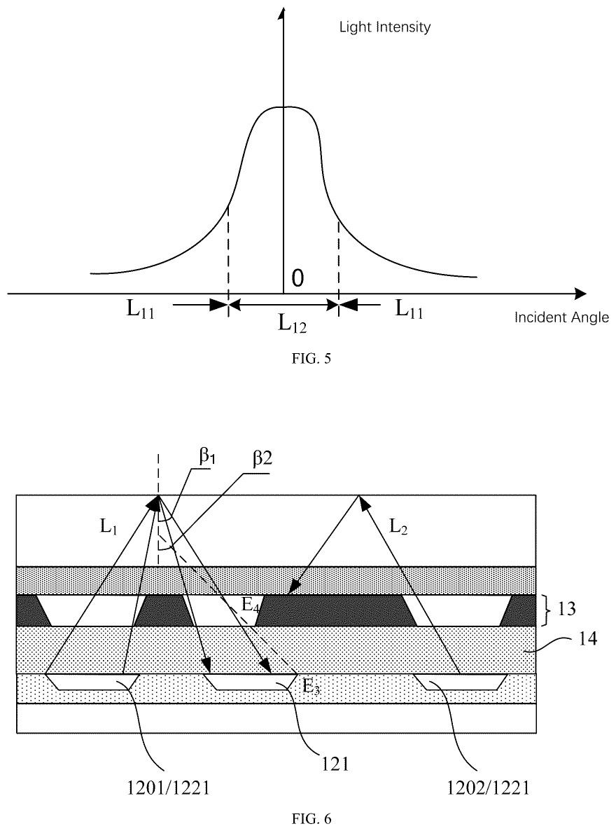

Referring to a schematic diagram of correspondence between an output angle and light intensity of a light-emitting unit shown in FIG. 5, taking the first light-emitting unit 1221 as an example, the first visible light L₁ emitted by the first light-emitting unit 1221 includes a first visible light L₁₁ with a large angle and a first visible light L₁₂ with a small angle. Light intensity of the first visible light L₁₂ with the small angle is stronger than light intensity of the first visible light L₁₁ with the large angle. Therefore, in a manner of configuration mentioned above, the photosensitive unit 121 in the same pixel may receive more first visible light Ly with smaller incident angle. Since the light intensity of the first visible light Ly with smaller incident angle is stronger, the signal intensity of the first visible light L₁ received by the photosensitive unit 121 is increased, that is, the intensity of useful signal received by the photosensitive unit 121 is improved, thereby improving a signal-to-noise ratio.

In an embodiment, as shown in FIG. 3a and FIG. 3b, in one pixel 12, on a cross section passing through the first center line CL₁ and the second center line CL₂, the photosensitive unit 121 has a first edge closer to the first light-emitting unit 1221. The light guiding structure 132 corresponding to the photosensitive unit 121 has a second edge E₂ located between the first center line CL₁ and the third center line CL₃. A shortest distance d₁ between the first edge E₁ and the first center line CL₁ is greater than a shortest distance d₂ between the second edge E₂ and the first center line CL₁, that is, the second edge E₂ of the light guiding structure 132 is closer to the first light-emitting unit 1221 than the first edge E₁ of the photosensitive unit 121.

In a case that an area of an opening of the light guiding structure 132 remains constant, by setting the second edge E₂ of the light guiding structure 132 closer to the first light-emitting unit 1221 than the first edge E₁ of the photosensitive unit 121, the first visible light L₁₂ with the small angle directed into the light guiding structure 132 may be increased and the first visible light L₁₁ with the large angle directed into the light guiding structure 132 may be reduced. As shown in FIG. 3a, the light intensity of the first visible light L₁₂ with the small angle is greater than the light intensity of the first visible light L₁₁ with the large angle. Therefore, the light intensity of the first visible light L₁ collected by the photosensitive unit 121 may be increased, thereby improving accuracy of fingerprint recognition.

In an embodiment, as shown in FIG. 3a and FIG. 3b, an angle between the first visible light L₁ detected by the photosensitive unit 112 and the first center line CL₁ is configured with a minimum angle α₁. For example, the minimum angle may be 0 degrees. An angle α₂ between a line connecting the first edge E₁ and the second edge E₂ and the first center line CL₁ is greater than or equal to the minimum angle α₁. Either the first edge E₁ or the second edge E₂ may be a straight line or a curve. The line connecting the first edge E₁ and the second edge E₂ may be represented by a line connecting an endpoint, closer to the substrate 11, of the first edge E₂ and an endpoint, further away from the substrate 11, of the second edge E₁. In this configuration, the first visible light Ly with an incident angle greater than or equal to the minimum angle α₁ may be ensured to be received by the photosensitive unit 121, thereby further increasing the light intensity of the first visible light L₁ detected by the photosensitive unit 121, and improving a signal-to-noise ratio.

In an embodiment, as shown in FIG. 3a and FIG. 3b, the light guiding layer 13 includes a light absorbing structure 131. The light absorbing structure 131 is provided with a plurality of first openings, and each of the plurality of light guiding structures 132 is located within the corresponding first opening. Exemplarily, the light absorbing structure 131 is a black color resistance. The material of the light guiding structure 132 may be a transparent material.

In an embodiment, as shown in FIG. 3a and FIG. 3b, the display panel may further include a substrate 11, and the plurality of pixels 12 are provided on the substrate 11. The light absorbing structure 131 is further provided with a plurality of second openings. The light guiding layer 13 may further include a plurality of first color resistance structures 133. Each of the first color resistance structures 133 is located within the corresponding second opening. Exemplarily, the light guiding structure 132 is a color resistor and has a same color as the first color resistance structure 133. In this case, the light guiding structure 132 and the first color resistance structure 133 may be prepared simultaneously, thereby simplifying a preparation process.

In an embodiment, as shown in FIG. 3a and FIG. 3b, colors of the first visible light emitted by the first light-emitting unit 1221, the light guiding structure 132, and the first color resistance structure 133 are all green. In comparison among three primary color light emitting unit, that is, comparison among the red light-emitting unit, the green light-emitting unit and the blue light-emitting unit, it can be seen that the green light-emitting unit has a relatively highest light output efficiency. Therefore, by configuring the photosensitive unit 121 to detect a green light emitted by the green light-emitting unit, accuracy of fingerprint recognition may be improved. Meanwhile, by configuring the light guiding structure 132 to be a green resistance structure, reflection interference of ambient light in the display panel may be reduced, thereby improving display contrast.

In an embodiment, as shown in FIG. 3a and FIG. 3b, an orthographic projection of each first light-emitting unit 1221 on the substrate 11 is located within an orthographic projection of the corresponding first color resistance structure 133 on the substrate 11. Alternatively, the orthographic projection of each first light-emitting unit 1221 on the substrate 11 coincides with the orthographic projection of the corresponding first color resistance structure 133 on the substrate 11. Thus, it may be ensure that as much of the first visible light Ly emitted by the first light-emitting unit 1221 pass through the first color resist structure 133 as possible, so that a light output rate is improved, thereby improving contrast of the display panel.

In an embodiment, as shown in FIG. 3a and FIG. 3b, part of an orthographic projection of the photosensitive unit 121 on the substrate 11 is located within an orthographic projection of the light absorbing structure 131 on the substrate 11, rather than the entire orthographic projection of the photosensitive unit 121 on the substrate 11 being located within the orthographic projection of the light guiding structure 132 on the substrate 11. Thus, the light absorbing structure 131 may be used for absorbing a first visible light emitted by a first light-emitting unit 1221 of an adjacent pixel as noise, thereby reducing the noise of fingerprint recognition, and improving a signal-to-noise ratio of fingerprint recognition.

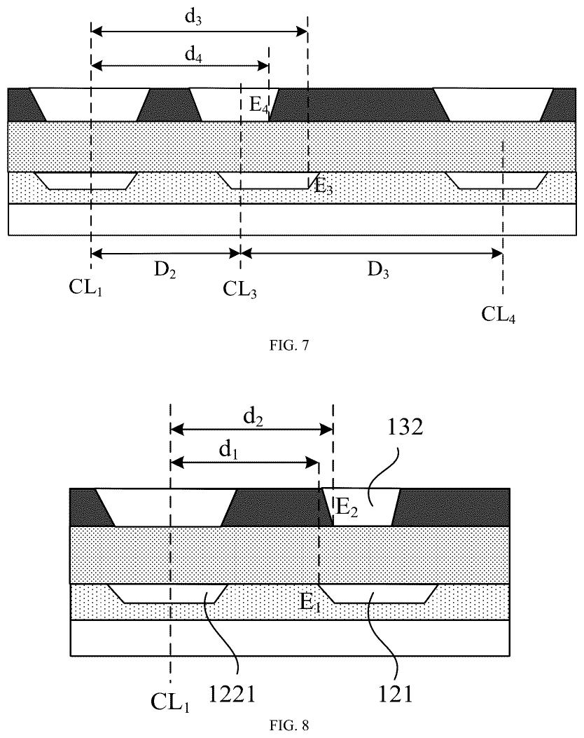

FIG. 6 is a cross-sectional view of a structure shown in FIG. 2 along A1A3. FIG. 7 is a local view of the structure shown in FIG. 6. As shown in FIG. 6 and FIG. 7, among two adjacent pixels 12, the first light-emitting unit 1221 of one pixel 12 has a first center line CL₁, and the first center line CL₁ is a straight line passing through a center of the first light-emitting unit 1221 of the pixel 12 in a vertical direction. The photosensitive unit 121 of the pixel 12 has a second center line CL₂, and the second center line CL₂ is a straight line passing through a center of the photosensitive unit 121 of the pixel 12 in the vertical direction. The light guiding structure 132 corresponding to the photosensitive unit 121 of the pixel 12 has a third center line CL₃, and the third center line CL₃ is a straight line passing through a center of the light guiding structure 132 corresponding to the photosensitive unit 121 of the pixel 12 in the vertical direction. A first light-emitting unit 1221 of the other pixel 12 has a fourth center line CL₄, and the fourth center line CL₄ is a straight line passing through a center of the first light-emitting unit 1221 of the other pixel in the vertical direction. A second shortest distance D₂ is a shortest distance between the third center line CL₃ and the first center line CL₁. A third shortest distance D₃ is a shortest distance between the third center line CL₃ and the fourth center line CL₄. The second shortest distance D₂ is less than the third shortest distance D₃.

Similar to representation of the second shortest distance D₂, the third shortest distance D₃ between the third center line CL₃ and the fourth center line CL₄ refers to a perpendicular line drawn from any point on the third center line CL₃ to the fourth center line CL₄, and the length of this perpendicular line is the third shortest distance D₃.

To facilitate description, the pixel 12 and another pixel adjacent to the pixel 12 are respectively referred to as a first pixel 1201 and a second pixel 1202. The second shortest distance D₂ is less than the third shortest distance D₃, that is, the first light-emitting unit 1221 of the first pixel 1201 is closer to the light guiding structure 132 corresponding to the photosensitive unit 121 of the first pixel 1201 than the first light-emitting unit 1221 of the second pixel 1202. In this case, the intensity of the first visible light L₁ emitted by the first light-emitting unit 1221 of the first pixel 1201 and received by the light guiding structure 132 is greater than the intensity of the first visible light L₂ emitted by the first light-emitting unit 1221 of the second pixel 1202 as noise, thereby increasing the intensity of useful signal received by the photosensitive unit 121 in the first pixel 1201, and further improving the signal-to-noise ratio.

In an embodiment, as shown in FIG. 6 and FIG. 7, in one pixel 12, on a cross-section passing through the first center line CL₁ and the second center line CL₂, the photosensitive unit 121 has a third edge E₃ further away from the first center line CL₁, of the photosensitive unit 121. The light guiding structure 132 corresponding to the photosensitive unit 121 has a fourth edge E₄ further away from the first center line CL₁, of the light guiding structure 132 corresponding to the photosensitive unit 121. A shortest distance d₃ between the third edge E₃ and the first center line CL₁ is greater than a shortest distance d₄ between the fourth edge E₄ and the first center line CL₁. In this configuration, the first visible light emitted by the first light-emitting unit 1221 of the adjacent pixel (i.e., the second pixel 1202) and received by the photosensitive unit 121 of the first pixel as noise may be reduced, thereby improving the signal-to-noise ratio.

In an embodiment, as shown in FIG. 6 and FIG. 7, an angle between the first visible light L₁ detected by the photosensitive unit 121 and the first center line CL₁ is configured with a maximum angle β₁. Exemplarily, the maximum angle β₁ is 10 degrees. An angle β₂ between a line connecting the third edge E₃ and the fourth edge E₄ and the first center line CL₁ is greater than or equal to the maximum angle β₁. Either the third edge E₃ or the fourth edge E₄ may be a straight line or a curve. The line connecting the third edge E₃ and the fourth edge E₄ may be represented by a line connecting an endpoint, closer to the substrate 11, of the third edge E₃ and an endpoint, further away from the substrate 11, of the fourth edge. Thus, the first visible light Ly with an incident angle less than or equal to the maximum angle β₁ may be ensured to be received by the photosensitive unit 121, thereby further improving the signal intensity of the first visible light L₁ detected by the photosensitive unit 121, and improving the signal-to-noise ratio.

In an embodiment, the angle between the first visible light L₁ detected by the photosensitive unit 121 and the first center line CL₁ is configured to be greater than or equal to 0 degrees and less than or equal to 10 degrees. Exemplarily, the above angle may be configured to be 0 degrees, 5 degrees, or 10 degrees.

In an embodiment, as shown in FIG. 6, the display panel may further include a thin film encapsulation layer 14. Exemplarily, the thin film encapsulation layer 14 includes a first inorganic layer, an organic layer, and a second inorganic layer sequentially stacked in a direction away from the substrate 11. Exemplarily, the light guiding layer 13 may be provided in the organic layer.

In an embodiment, the display panel may further include a driving circuit (not shown in FIG. 6) located on a side, close to the substrate 11, of the photosensitive unit 121 and the light-emitting unit 122. Specifically, the driving circuit may include a pixel circuit and a detection circuit. The pixel circuit is connected to the light-emitting unit 122 and is configured to drive the light-emitting unit 122 to emit light at a predetermined brightness. The detection circuit is connected to the photosensitive unit 121 and is configured to detect magnitude of electrical signals output by the photosensitive unit 121. Exemplarily, both the pixel circuit and the detection circuit include thin film transistors. Therein, a material of an active layer of a thin film transistor in the pixel circuit is Low Temperature Polycrystalline Oxide (LTPO), and a material of an active layer of a thin film transistor in the detection circuit is In—Ga—Zn—O (IGZO).

FIG. 8 is a local cross-sectional view of a structure of a display panel according to another embodiment of the present disclosure. By comparing the display panels shown in FIG. 8 and FIG. 3b, it can be seen that a difference between the display panel provided in this embodiment and the display panel shown in FIG. 3b lies in that in this embodiment, a shortest distance d₁ between the first edge E₁ and the first center line CL₁ is less than a shortest distance d₂ between the second edge E₂ and the first center line CL₁. That is, the second edge E₂ of the light guiding structure 132 is further away from the first light-emitting unit 1221 than the first edge E₁ of the photosensitive unit 121. Thus, all of the first visible light Ly entering the light guiding structure 132 can be collected by the photosensitive unit 121, thereby reducing losses.

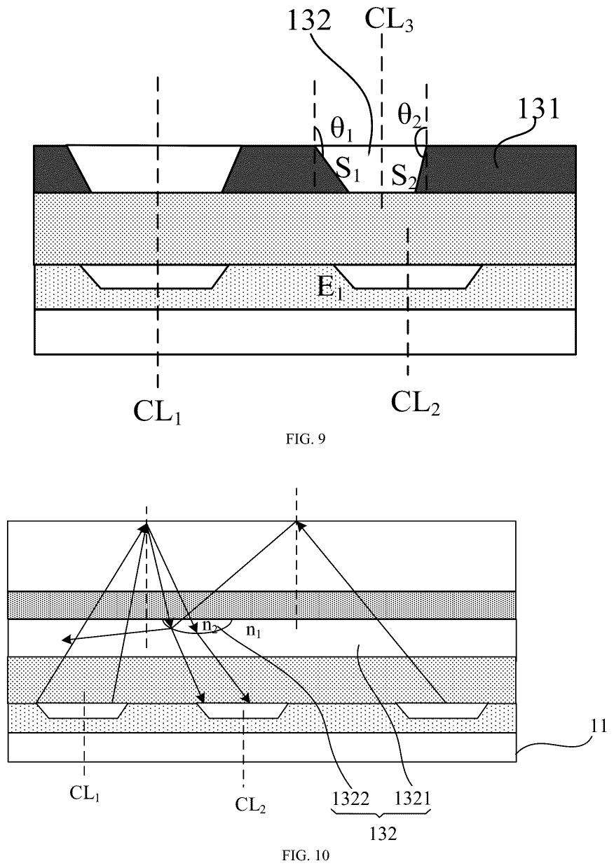

FIG. 9 is a local cross-sectional view of a structure of a display panel according to still another embodiment of the present disclosure. By comparing the display panels shown in FIG. 9, FIG. 3b, and FIG. 8, it can be seen that a difference between the display panel provided in this embodiment and the display panels shown in FIG. 3b and FIG. 8 lies in that in this embodiment, on a cross-section passing through the first center line CL₁ and the second center line CL₂, a cross-sectional shape of the first opening defined by the light absorbing structure 131 is irregular, such as a non-centrosymmetric shape.

Specifically, on the cross-section passing through the first center line CL₁ and the second center line CL₂, an inner wall, located between the first center line CL₁ and the third center line CL₃, of the first opening defined by the light absorbing structure 131 is configured to be a first inner wall S₁. A first angle θ₁ is an angle between the first inner wall S₁ and the first center line CL₁. An inner wall, located between the second center line CL₂ and the third center line CL₃, of the first opening defined by the light absorbing structure 131 is configured to be a second inner wall S₂. A second angle θ₂ is an angle between the second inner wall S₂ and the second center line CL₂. The second angle θ₂ is greater than or equal to the first angle θ₁. That is, an inclination degree, towards a direction closer to the substrate 11, of the first inner wall S₁ is equal to or greater than that of the second inner wall S₂. Thus, within one pixel 12, more first visible light L₁ may be directed by the light guiding structure 132 and more noise may be absorbed, thereby improving the signal-to-noise ratio.

FIG. 10 is a cross-sectional view of a structure of a display panel according to still another embodiment of the present disclosure. By comparing the display panel shown in FIG. 10 and the display panels provided in any of embodiments mentioned above, it can be seen that the light guiding structure 132 in the display panel provided in this embodiment is different from that in any of the above embodiments. The light guiding structure in this embodiment includes a lens structure.

Specifically, as shown in FIG. 10, in this embodiment, the light guiding structure 132 includes a first light transmitting unit 1321 and a second light transmitting unit 1322. The first light transmitting unit 1321 is located above the corresponding pixel. A refractive index of the first light transmitting unit 1321 is a first refractive index n₁ and the first light transmitting unit 1321 includes a first groove concaved toward the corresponding pixel. The first groove is filled by the second light transmitting unit 1322 and a refractive index of the second light transmitting unit 1322 is a second refractive index n₂. The second refractive index n₂ is greater than the first refractive index n₁. Thus, an interface between the first light transmitting unit 1321 and the second light transmitting unit 1322 forms a lens structure at the first groove.

On a cross-section passing through the first center line CL₁ and the second center line CL₂, a shape of the first groove may be triangular, trapezoidal, hemispherical, and so on. The shape of the first groove determines a shape of the second light transmitting unit 1322.

In an embodiment, on the cross-section passing through the first center line CL₁ and the second center line CL₂, the shape of the cross-section of the second light transmitting unit 1322 filled in the first groove is arched, so that the interface between the first light transmitting unit 1321 and the second light transmitting unit 1322 is a smooth curved surface, which plays a role in buffering stress.

FIG. 11 is a cross-sectional view of a structure of a display panel according to yet still another embodiment of the present disclosure. By comparing the display panels shown in FIG. 11 and FIG. 10, it can be seen that a difference between the display panels shown in FIG. 11 and FIG. 10 lies in that in this embodiment, the light guiding structure 132 is an irregular structure, such as a non-centrosymmetric structure.

Specifically, an interface is formed between the first light transmitting unit 1321 and the second light transmitting unit 1322. On a cross-section passing through the first center line CL₁ and the second center line CL₂, a part of the interface, located between the first center line CL₁ and the third center line CL₃, has a first curvature K₁. The other part of the interface, located between the second center line CL₂ and the third center line CL₃, has a second curvature K₂. The first curvature K₁ is not equal to the second curvature K₂.

For example, the first curvature K₁ is less than the second curvature K₂, that is, the part of the interface located between the first center line CL₁ and the third center line CL₃ is closer to the second center line CL₂ than the other part of the interface located between the second center line CL₂ and the third center line CL₃, which is equivalent to shrinking the interface between the first center line CL₁ and the third center line CL₃, thereby reducing a size of the interface. Thud, the interface is avoided from extending above the first light-emitting unit 1221, so that light output of the first light-emitting unit 1221 may not be affected, thereby avoiding display abnormalities.

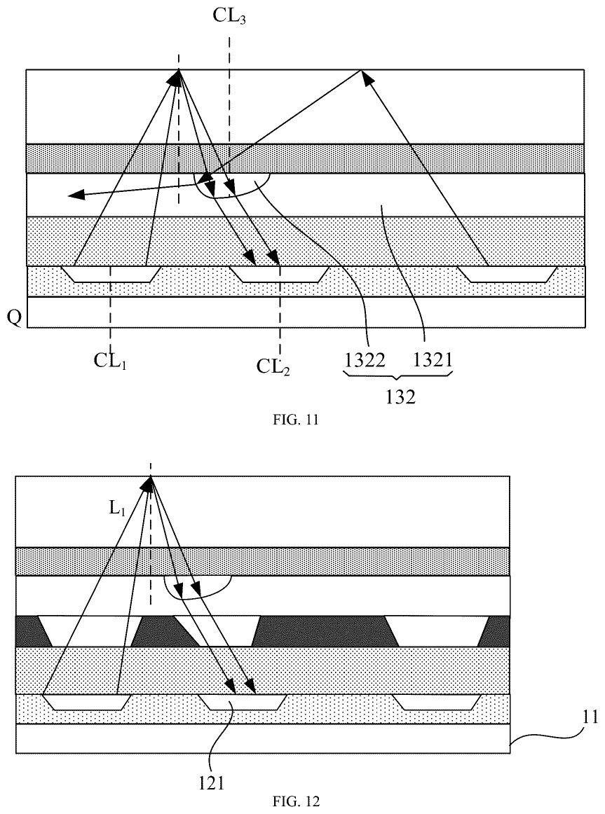

FIG. 12 is a cross-sectional view of a structure of a display panel according to yet still another embodiment of the present disclosure. As shown in FIG. 12, the light guiding structure 132 in the display panel provided in this embodiment is equivalent to a combination of a lens structure shown in FIG. 11 and a light guiding layer 13 shown in FIG. 3a, that is, the light guiding structure 132 includes the lens structure shown in FIG. 11 and the light guiding layer 13 shown in FIG. 3a. The lens structure is located on a side, away from the substrate 11, of the light guiding layer 13. The first visible light L₁ sequentially passes through the lens structure and a color resistance structure in the light guiding layer 13, and then enters the photosensitive unit 121.

Implementation details of the lens structure may be referred to the embodiment shown in FIG. 11, and implementation details of the light guiding layer may be referred to the embodiment shown in FIG. 3a, which will not be described herein again.

The embodiment only takes the lens structure shown in FIG. 11 and the light guiding layer shown in FIG. 3a as examples. The lens structure may also be replaced with the lens structure of the display panel shown in FIG. 10, and the light guiding layer may also be replaced with the light guiding layer of the display panel shown in FIG. 9.

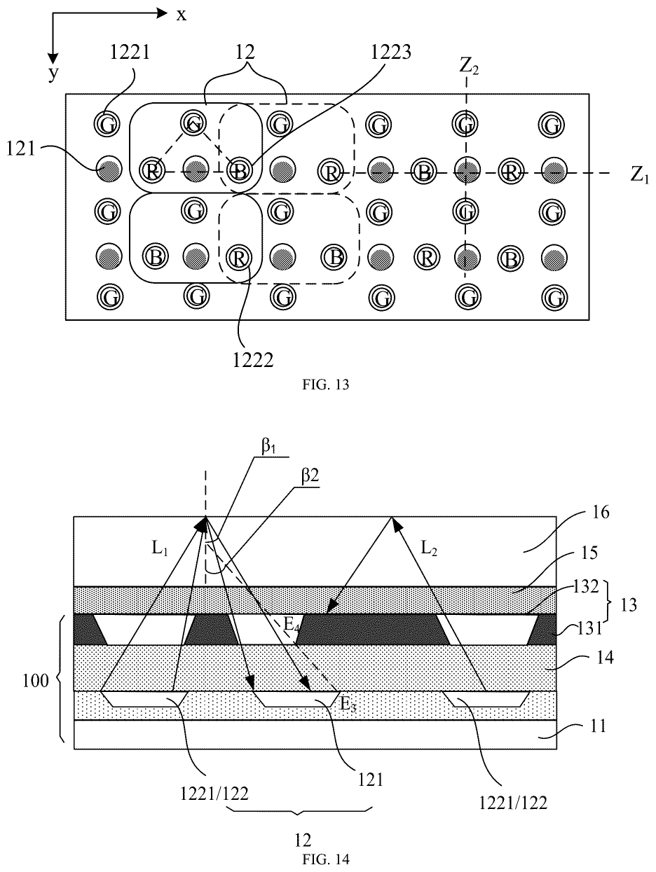

FIG. 13 is a schematic diagram of the structure of a display panel according to yet still another embodiment of the present disclosure. As shown in FIG. 13, a plurality of pixels 12 are provided on the substrate 11. In one pixel 12, the pixel 12 includes a plurality of light-emitting units 122 and the plurality of light-emitting units 122 further include a second light-emitting unit 1222 and a third light-emitting unit 1223. The second light-emitting unit 1222 is configured to emit at least a second visible light, and the third light-emitting unit 1223 is configured to emit at least a third visible light. Colors of the first visible light, the second visible light, and the third visible light are different from each other. For example, the first light-emitting unit 1221 is a green light-emitting unit G, the second light-emitting unit 1222 is a red light-emitting unit R, and the third light-emitting unit 1223 is a blue light-emitting unit B.

In one pixel 12, a virtual polygon is formed by connecting centers of the first light-emitting unit 1221, the second light-emitting unit 1222, the third light-emitting unit 1223, and the photosensitive unit 121, such as a triangle as shown in FIG. 13. In a first direction x parallel to the substrate 11, two adjacent pixels 12 share a second light-emitting unit 1222, or two adjacent pixels 12 share a third light-emitting unit 1223.

In an embodiment, in the first direction x parallel to the substrate 11, the center of the second light-emitting unit 1222, the center of the third light-emitting unit 1223, and the center of the photosensitive unit 121 in two adjacent pixels are located on a straight line Z₁.

In an embodiment, in a second direction y parallel to the substrate 11, the center of the first light-emitting unit 1221 and the center of the photosensitive unit 121 in two adjacent pixels 12 are located on a straight line Z₂. An angle between the first direction x and the second direction y is greater than 0 degrees. Preferably, the first direction x is perpendicular to the second direction y.

In an embodiment, the plurality of pixels 12 are divided into a plurality of row pixel groups in the second direction y. When the n-th row pixel group is configured to display, the (n-m)-th row pixel group is configured not to display. That is, the display panel is controlled to display in a staggered manner. Preferably, a value of m is 1 or 2. Thus, in the process of fingerprint recognition, light emitted by the n-th row pixel group may be detected by the photosensitive unit 121 and light from the (n-m)-th row pixel group may not be detected, thereby avoiding the light from the (n-m)-th row pixel group from interfering with the light emitted by the n-th row pixel group, and thereby improving the signal-to-noise ratio of fingerprint recognition.

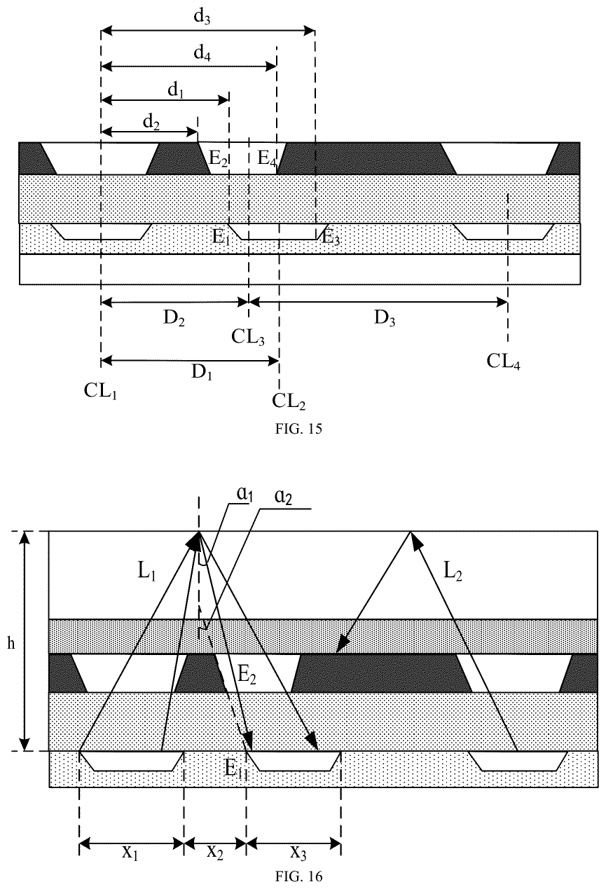

The present embodiment further provides a display module. FIG. 14 is a cross-sectional view of a structure of a display module according to an embodiment of the present disclosure. FIG. 15 is a first local view of the structure of the display module shown in FIG. 14. FIG. 16 is a second local view of the structure of the display module shown in FIG. 14. As shown in FIG. 14, FIG. 15, and FIG. 16, the display module includes a display panel 100. The display panel 100 includes a plurality of pixels 12 and a light guiding layer 13. At least part of the pixels 12 includes a photosensitive unit 121 and a plurality of light-emitting units 122. The plurality of light-emitting units 122 include a first light-emitting unit 1221, configured to emit at least a first visible light L₁. The photosensitive unit 121 is configured to detect the first visible light L₁. The light guiding layer 13 is located above the display panel 100 and includes a plurality of light guiding structures 132. The first visible light Ly emitted by the first light-emitting unit 122 is received by the corresponding photosensitive unit 121 through the corresponding light guiding structure 132.

In one pixel 12, the first light-emitting unit 1221 has a first center line CL₁, and the first center line CL₁ is a straight line passing through a center of the first light-emitting unit 1221 in a vertical direction. The photosensitive unit 121 has a second center line CL₂, and the second center line CL₂ is a straight line passing through a center of the photosensitive unit 121 in the vertical direction. The light guiding structure 132 corresponding to the photosensitive unit 121 has a third center line CL₃, and the third center line CL₃ is a straight line passing through a center of the light guiding structure 132 corresponding to the photosensitive unit 121 in the vertical direction. A first shortest distance D₁ is a shortest distance between the second center line and the first center line, and a second shortest distance D₂ is a shortest distance between the third center line CL₃ and the first center line CL₁. The first shortest distance D₁ is greater than the second shortest distance D₂.

According to the display module provided in this embodiment, in one pixel 12, the first shortest distance D₁ is configured to be greater than the second shortest distance D₂, that is, in a thickness direction of the substrate 11, an orthographic projection of the photosensitive unit 121 on the substrate 11 does not coincides with an orthographic projection of the light guiding structure 132 on the substrate 11. The third center line CL₃ of the light guiding structure 132 is closer to the first light-emitting unit 1221 than the second center line CL₂ of the photosensitive unit 121. In this case, the photosensitive unit 121 in the same pixel may receive more first visible light Ly with smaller incident angle. Since the intensity of the first visible light with smaller incident angle is stronger, the signal intensity of the first visible light L₁ received by the photosensitive unit 121 is improved, thereby improving the signal-to-noise ratio.

In an embodiment, as shown in FIG. 14 and FIG. 15, among two adjacent pixels 12, the first light-emitting unit 1221 of one pixel 12 has a first center line CL₁, and the first center line CL₁ is a straight line passing through a center of the first light-emitting unit 1221 of a pixel 12 in a vertical direction. The photosensitive unit 121 of the pixel 12 has a second center line CL₂, and the second center line CL₂ is a straight line passing through a center of the photosensitive unit 121 of the pixel 12 in the vertical direction. The light guiding structure 132 corresponding to the photosensitive unit 121 of the pixel 12 has a third center line CL₃, and the third center line CL₃ is a straight line passing through a center of the light guiding structure 132 corresponding to the photosensitive unit 121 of the pixel 12 in the vertical direction. The first light-emitting unit 1221 of the other pixel 12 has a fourth center line CL₄, and the fourth center line CL₄ the is a straight line passing through a center of the first light-emitting unit 1221 of the other pixel adjacent to the pixel 12 in the vertical direction. The second shortest distance D₂ is a shortest distance between the third center line CL₃ and the first center line CL₁, a third shortest distance D₃ is a shortest distance between the third center line CL₃ and the fourth center line CL₄, and the second shortest distance D₂ is less than the third shortest distance D₃.

In this case, intensity of the first visible light L₁ emitted by the first light-emitting unit 1221 of one pixel 12 and received by the light guiding structure 132 is greater than intensity of the first visible light L₂ emitted by the first light-emitting unit 1221 of the other pixel 12 as noise, thereby increasing the intensity of useful signal received by the photosensitive unit 121 in one pixel 12 and improving the signal-to-noise ratio.

As shown in FIG. 15 and FIG. 16, the display module is provided with a light-emitting surface. The photosensitive unit 121 and the first light-emitting unit 1221 are disposed in a same layer. At least two angles between the first visible light L₁ detected by the photosensitive unit 121 and the first center line CL₁ are configured with a minimum angle α₁ and a maximum angle β₁. In one pixel 12, on a cross-section passing through the first center line CL₁ and the second center line CL₂, a first dimension x₁ is a width of the first light-emitting unit 1221, a second dimension x₂ is a distance between the first light-emitting unit 1221 and the photosensitive unit 121, a third dimension x₃ is a width of the photosensitive unit 121, and a fourth dimension h is a shortest distance between the first light-emitting unit 1221 and the light-emitting surface. A first ratio is a ratio of one half of the second dimension x₂ to the fourth dimension h. A second ratio is a ratio of one half of a sum of the first dimension x₁, the second dimension x₂, and the third dimension x₃ to the fourth dimension h. The x₂, and minimum angle α₁ is not less than an arctangent value of the first ratio, that is, α₁≥arctan x₂/2h, and the maximum angle β₁ is not less than an arctangent value of the second ratio, that is, β₁≥arctan x₁+x₂+x₂/2h. Thus, the first dimension x₁, the second dimension x₂, the third dimension x₃, and the fourth dimension h may be calculated based on the minimum angle α₁ and the maximum angle β₁.

The angle between the first visible light L₁ detected by the photosensitive unit 121 and the first center line CL₁ is configured to be greater than or equal to 0 degrees and less than or equal to 10 degrees. Exemplarily, the angle may be configured to be 0 degrees, 5 degrees, or 10 degrees. In an embodiment, during the preparation of the display module, the minimum angle α₁ is set to 0 degrees and the maximum angle β₁ is set to 10 degrees. Alternatively, in other embodiments, the minimum angle α₁ is set to 5 degrees and the maximum angle β₁ is set to 10 degrees. The first dimension x₁, the second dimension x₂, the third dimension x₃, and the fourth dimension h mentioned above may be further calculated based on the minimum angle α₁ configured as 0 degrees and the maximum angle β₁ configured as 10 degrees. Alternatively, the first dimension x₁, the second dimension x₂, the third dimension x₃, and the fourth dimension h mentioned above may be further calculated based on the minimum angle α₁ configured as 5 degrees and the maximum angle β₁ configured as 10 degrees.

As shown in FIG. 14 and FIG. 15, in one pixel 12, on a cross section passing through the first center line CL₁ and the second center line CL₂, the photosensitive unit 121 has a first edge E₁ closer to the first light-emitting unit 1221, and the light guiding structure 132 corresponding to the photosensitive unit 121 has a second edge E₂ located between the first center line CL₁ and the third center line CL₂. A shortest distance d₁ between the first edge E₁ and the first center line CL₁ is greater than a shortest distance d₂ between the second edge E₂ and the first center line CL₁, that is, the second edge E₂ of the light guiding structure 132 is closer to the first light-emitting unit 1221 than the first edge E₁ of the photosensitive unit 121.

According to the display module provided in this embodiment, under the premise that the area of the opening of the light guiding structure 132 remains constant, by setting the second edge E₂ of the light guiding structure 132 closer to the first light-emitting unit 1221 than the first edge E₁ of the photosensitive unit 121, it is possible to increase the first visible light L₁₂ with the small angle directed into the light guiding structure 132 and reduce the first visible light L₁₁ with the large angle directed into the light guiding structure 132. As shown in FIG. 3a, the light intensity of the first visible light L₁₂ with the small angle is greater than the light intensity of the first visible light L₁₁ with the large angle. Therefore, the light intensity of the first visible light L₁ collected by the photosensitive unit 121 may be increased, thereby improving accuracy of fingerprint recognition.

As shown in FIG. 14 and FIG. 16, in an embodiment, the angle α₂ between a line connecting the first edge E₁ and the second edge E₂ and the first center line CL₁ is greater than or equal to the minimum angle α₁. In this configuration, the first visible light Ly with an angle greater than or equal to the minimum angle α₁ may be ensured to be received by the photosensitive unit 121, thereby further increasing the light intensity of the first visible light L₁ detected by the photosensitive unit 121, and improving the signal-to-noise ratio.

As shown in FIG. 14 and FIG. 15, in an embodiment, in the same pixel 12, on the cross-section passing through the first center line CL₁ and the second center line CL₂, the photosensitive unit 121 has a third edge E₃ further away from the first center line CL₁, and the light guiding structure 132 corresponding to the photosensitive unit 121 has a fourth edge E₄ further away from the first center line CL₁. A shortest distance d₃ between the third edge E₃ and the first center line CL₁ is greater than a shortest distance d₄ between the fourth edge E₄ and the first center line CL₁. Thus, the first visible light emitted by the first light-emitting unit 1221 of the adjacent pixel (i.e., the second pixel 1202) and received by the first pixel as noise may be reduced, thereby improving the signal-to-noise ratio.

As shown in FIG. 14, in an embodiment, an angle β₂ between a line connecting the third edge E₃ and the fourth edge E₄ and the first center line CL₁ is greater than or equal to the maximum angle β₁. Thus, the first visible light L₁, which has an angle less than or equal to the maximum angle β₁, may be received by the photosensitive unit 121, thereby further improving the signal intensity of the first visible light L₁ detected by the photosensitive unit 121, and improving the signal-to-noise ratio.

As shown in FIG. 14, in an embodiment, the display panel 110 further includes a substrate 11, the plurality of pixels 12 are disposed on the substrate 11, and part of an orthographic projection of the light guiding structure 132 on the substrate 11 is located outside an orthographic projection of the photosensitive unit 121 on the substrate 11. Thus, the light guiding structure 132 may be closer to the first light-emitting unit 1221 compared to the photosensitive unit 121 in a direction parallel to the substrate 11 and further away from a first light-emitting unit 1221 of an adjacent pixel, thereby improving the signal-to-noise ratio.

As shown in FIG. 14, in an embodiment, the light guiding layer 13 further includes a light absorbing structure 131. The light absorbing structure 131 is provided with a plurality of first openings, and each of the light guiding structures 132 is located within the corresponding first opening.

As shown in FIG. 14, in an embodiment, the light guiding layer 13 further includes a first color resistance structure. Specifically, the plurality of pixels 12 are disposed on the substrate 11, and the light absorbing structure 131 is further provided with a plurality of second openings. The light guiding layer 13 further includes a plurality of first color resistance structures 133, and each of the first color resistance structures 133 is located within the corresponding second opening. An orthographic projection of each first light-emitting unit 1221 on the substrate 11 is located within an orthographic projection of the corresponding first color resistance structure on the substrate 11. That is, an area of the second opening is larger than an area of the first light-emitting unit 1221. Alternatively, the orthographic projection of each first light-emitting unit 1221 on the substrate 11 coincides with the orthographic projection of the corresponding first color resistance structure on the substrate 11, thereby improving display contrast of the display panel 100.

As shown in FIG. 14, in an embodiment, part of an orthographic projection of the photosensitive unit 121 on the substrate 11 is located within an orthographic projection of the light absorbing structure 131 on the substrate 11. In this way, the light absorbing structure 131 may be used for absorbing the first visible light emitted by the first light-emitting unit 1221 from adjacent pixels as noise, thereby reducing noise during fingerprint recognition, and improving the signal-to-noise ratio of fingerprint recognition.

In an embodiment, a material of the light guiding structure 132 is a transparent material. For example, the light guiding structure 132 is a color resistor, and the light guiding structure 132 has a same color as the first color resistance structure. The color of the first light-emitting unit 1221, the color of the light guiding structure 132, and the color of the first color resistance structure are all green. In comparison among the red light-emitting unit, the green light-emitting unit, and the blue light-emitting unit, it can be seen that the green light-emitting unit has a relatively highest light output efficiency. Therefore, by configuring the photosensitive unit 121 to detect a green light emitted by the green light-emitting unit, the accuracy of fingerprint recognition may be improved. Meanwhile, by configuring the light guiding structure 132 to be a green resistance structure, reflection interference of ambient light in the display panel may be reduced, thereby improving display contrast.

In an embodiment, the light absorbing structure 131 may be a black color resistance.

In an embodiment, the light guiding layer 13 may be multiplexed as a color film layer.

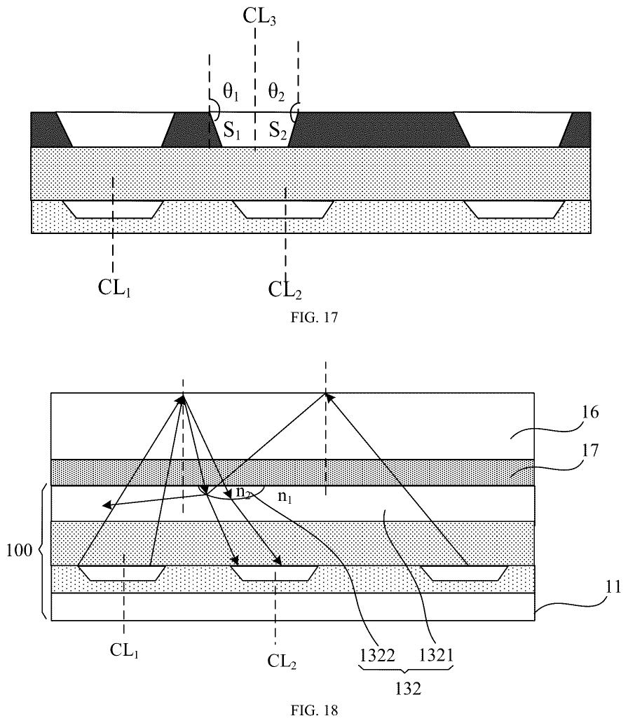

FIG. 17 is a third local view of a structure of the display module shown in FIG. 14. As shown in FIG. 14, FIG. 16 and FIG. 17, in an embodiment, on a cross-section passing through the first center line CL₁ and the second center line CL₂, an inner wall, located between the first center line CL₁ and the third center line CL₃, of the first opening formed in the light absorbing structure 131 is configured to be a first inner wall S₁. A first angle θ₁ is an angle between the first inner wall S₁ and the first center line CL₁. The first angle θ₁ is not less than the minimum angle α₁, thereby improving the signal intensity of the first light-emitting unit 113 detected by the photosensitive unit 112.

In an embodiment, as shown in FIG. 17, on the cross-section passing through the first center line CL₁ and the second center line CL₂, An inner wall, located between the second center line CL₂ and the third center line CL₃, of the first opening formed in the light absorbing structure 131 is configured to be a second inner wall S₂. A second angle θ₂ is an angle between the second inner wall S₂ and the second center line C₂, and the second angle θ₂ is not less than the first angle θ₁. That is, inclination, towards a direction closer to the substrate 11, of the first inner wall S₁ is equal to or greater than that of the second inner wall S₂. Thus, within one pixel 12, more first visible light L₁ can be directed into the light guiding structure 132 and more noise can be absorbed, thereby improving the signal-to-noise ratio.

In an embodiment, as shown in FIG. 14, the display module may further include an over coat (OC) 15 and a cover plate 16 sequentially stacked on a side, away from the substrate 11, of the light guiding layer 13. The OC 15 and the cover plate 16 are fixed by optical adhesive bonding.

In an embodiment, the display module may further include a touch metal layer (not shown in FIG. 14) located between a thin film encapsulation layer 14 and the light-emitting unit 122 and the photosensitive unit 121.

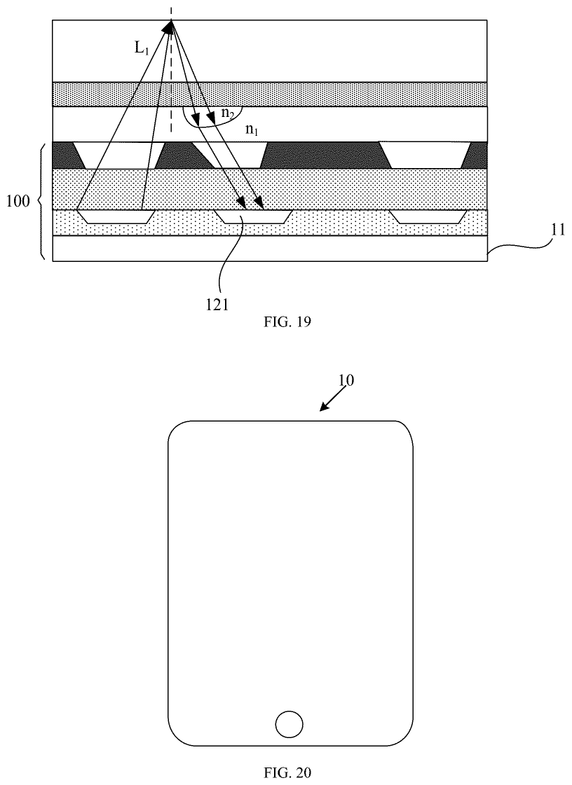

FIG. 18 is a schematic diagram of a structure of a display module according to another embodiment of the present disclosure. As shown in FIG. 18, a difference between the display modules provided in this embodiment and any of the embodiments mentioned above lies in that in this embodiment, the light guiding structure 132 is a lens structure. Specifically, the light guiding structure 132 includes a first light transmitting unit 1321 and a second light transmitting unit 1322. The first light transmitting unit 1321 is located above the corresponding pixel. A refractive index of the first light transmitting unit 1321 is a first refractive index n₁ and the first light transmitting unit 1321 includes a first groove concaved toward the corresponding pixel. The first groove is filled by the second light transmitting unit 1322 and a refractive index of the second light transmitting unit 1322 is a second refractive index n₂. The second refractive index n₂ is greater than the first refractive index n₁.

In an embodiment, on the cross-section passing through the first center line CL₁ and the second center line CL₂, a shape of the cross-section of the second light transmitting unit 1322 filled in the first groove is arched, so that the interface between the first light transmitting unit 1321 and the second light transmitting unit 1322 is a smooth curved surface, which plays a role in buffering stress.

In an embodiment, an interface is formed between the first light transmitting unit 1321 and the second light transmitting unit 1322. On a cross-section passing through the first center line CL₁ and the second center line CL₂, a part of the interface, located between the first center line CL₁ and the third center line CL₃, has a first curvature K₁. The other part of the interface, located between the second center line CL₂ and the third center line CL₃, has a second curvature K₂. The first curvature K₁ is not equal to the second curvature K₂. Preferably, the first curvature K₁ is less than the second curvature K₂, that is, the part of the interface located between the first center line CL₁ and the third center line CL₃ is closer to the second center line CL₂ than the other part of the interface located between the second center line CL₂ and the third center line CL₃, which is equivalent to shrinking the interface between the first center line CL₁ and the third center line CL₃, thereby reducing a size of the interface. Thud, the interface is avoided from extending above the first light-emitting unit 1221, so that light output of the first light-emitting unit 1221 may not be affected, thereby avoiding display abnormalities.

In an embodiment, as shown in FIG. 18, the display module further includes a cover plate 16, and the cover plate 16 is bonded and fixed to the display panel 100 through an optical adhesive layer 17.

FIG. 19 is a schematic diagram of the structure of a display module according to still another embodiment of the present disclosure. As shown in FIG. 19, in this embodiment, the light guiding layer 13 includes a light absorbing structure 131. The light absorbing structure 131 is provided with a plurality of first openings, and each of the light guiding structures 132 is located within the corresponding first opening. A plurality of lens structures are disposed with intervals, and each of the lens structures is located on a side, away from the display panel, of the corresponding light guiding structure 132.

In an embodiment, each of the lens structures includes a first light transmitting unit 1321 and a second light transmitting unit 1322. The first light transmitting unit 1321 is located on a side, away from the display panel 100, of the corresponding light guiding structure 132. A refractive index of the first light transmitting unit 1321 is a first refractive index n₁ and the first light transmitting unit 1321 includes a first groove concaved toward the corresponding light guiding structure 132, of the first light transmitting unit 1321. The first groove is filled by the second light transmitting unit 1322, and a refractive index of the second light transmitting unit 1322 is a second refractive index n₂. The second refractive index n₂ is greater than the first refractive index n₁.

The display panel in the display module according to any embodiment of the disclosure may employ the display panel provided in any of the embodiments described above. Technical details not described in the display module embodiment may be referred to the display panel embodiments, and are not described herein again.

The present embodiment further provides a display device. FIG. 20 is a schematic diagram of a structure of a display device according to an embodiment of the present disclosure. As shown in FIG. 20, the display device 10 includes a display panel 100 or a display module according to any of the above embodiments, and its technical principles and effects are similar, which are not described herein again.

It is understandable that the display panel 100 or the display module could also be applied to other display devices. For example, the display device may include a tablet computer, a computer monitor, a television, a wearable device, an information kiosk, or any other products or components with display functionality.

The above description, combined with specific embodiments, outlines the basic principles of the present disclosure. However, it should be noted that the advantages, benefits, and effects mentioned in this disclosure are exemplary and not limiting. It should not be assumed that these advantages, benefits, and effects are mandatory for each embodiment of the present disclosure. Additionally, the specific details disclosed above serve merely as examples for illustrative and comprehension purposes, and are not limiting. These details do not restrict the present disclosure to the implementation using the aforementioned specific details.

It should also be noted that in this disclosure, various components or steps can be separated and/or recombined. Such separation and/or recombination should be considered equivalent embodiments of this disclosure. Although multiple exemplary aspects and embodiments have been discussed above, those skilled in the art will recognize that certain variations, modifications, alterations, additions, and sub-combinations are possible.

What is claimed is:

1. A display panel, comprising:
a plurality of pixels, at least part of the plurality of pixels comprising a photosensitive unit and a plurality of light-emitting units, the plurality of light-emitting units comprising a first light-emitting unit, the first light-emitting unit configured to emit at least a first visible light, and the photosensitive unit configured to detect the first visible light; and
a light guiding layer provided above the plurality of pixels, comprising a plurality of light guiding structures, the first visible light emitted by the first light-emitting unit being received by a corresponding photosensitive unit through a corresponding light guiding structure;
wherein in one pixel, the first light-emitting unit has a first center line, the first center line is a straight line passing through a center of the first light-emitting unit in a vertical direction, the photosensitive unit has a second center line, the second center line is a straight line passing through a center of the photosensitive unit in the vertical direction, the light guiding structure corresponding to the photosensitive unit has a third center line, the third center line is a straight line passing through a center of the light guiding structure corresponding to the photosensitive unit in the vertical direction, a first shortest distance is a shortest distance between the second center line and the first center line, a second shortest distance is a shortest distance between the third center line and the first center line, and the first shortest distance is greater than the second shortest distance.

2. The display panel according to claim 1, wherein
the plurality of pixels comprise two adjacent pixels, the two adjacent pixels comprises a first pixel and a second pixel, among the two adjacent pixels, a first light-emitting unit of the first pixel has the first center line, a photosensitive unit of the first pixel has the second center line, and a light guiding structure corresponding to the photosensitive unit of the first pixel has the third center line, a first light-emitting unit of the second pixel has a fourth center line, the fourth center line is a straight line passing through a center of the first light-emitting unit of the second pixel in the vertical direction, and
a third shortest distance is a shortest distance between the third center line and the fourth center line, and the second shortest distance is less than the third shortest distance.

3. The display panel according to claim 1, wherein in one pixel,
on a cross-section passing through the first center line and the second center line, the photosensitive unit has a first edge close to the first light-emitting unit, the light guiding structure corresponding to the photosensitive unit has a second edge located between the first center line and the third center line, and a shortest distance between the first edge and the first center line is greater than a shortest distance between the second edge and the first center line.

4. The display panel according to claim 3, wherein an angle between the first visible light detected by the photosensitive unit and the first center line is configured with a minimum angle, and an angle between a line connecting the first edge and the second edge and the first center line is greater than or equal to the minimum angle; and
the minimum angle is 0 degrees.

5. The display panel according to claim 1, wherein
in one pixel, on a cross-section passing through the first center line and the second center line, the photosensitive unit has a third edge away from the first center line, the light guiding structure corresponding to the photosensitive unit has a fourth edge away from the first center line, and a shortest distance between the third edge and the first center line is greater than a shortest distance between the fourth edge and the first center line.

6. The display panel according to claim 5, wherein an angle between the first visible light detected by the photosensitive unit and the first center line is configured with a maximum angle, and an angle between a line connecting the third edge and the fourth edge and the first center line is greater than or equal to the maximum angle; and
the maximum angle is 10 degrees.

7. The display panel according to claim 1, further comprising a substrate, wherein the plurality of pixels are disposed on the substrate, and part of an orthographic projection of the light guiding structure on the substrate is located outside an orthographic projection of the photosensitive unit on the substrate; and
an angle between the first visible light detected by the photosensitive unit and the first center line is greater than or equal to 0 degrees and less than or equal to 10 degrees.

8. The display panel according to claim 1, the light guiding structure comprising:
a first light transmitting unit provided above the corresponding pixel, wherein the first light transmitting unit has a first refractive index and comprises a first groove concaved toward the corresponding pixel; and
a second light transmitting unit filled in the first groove, wherein the second light transmitting unit has a second refractive index, and the second refractive index is greater than the first refractive index.

9. The display panel according to claim 8, wherein on a cross-section passing through the first center line and the second center line, a cross-sectional shape of the second light transmitting unit filled in the first groove is arched;
the first light transmitting unit and the second light transmitting unit have an interface, and on the cross-section passing through the first center line and the second center line, the interface between the first center line and the third center line has a first curvature, the interface between the second center line and the third center line has a second curvature, and the first curvature is not equal to the second curvature; and
the first curvature is less than the second curvature.

10. The display panel according to claim 1, further comprising a substrate, wherein the plurality of pixels are disposed on the substrate, the plurality of light-emitting units further comprise a second light-emitting unit and a third light-emitting unit, the second light-emitting unit is configured to emit at least a second visible light, the third light-emitting unit is configured to emit at least a third visible light, and colors of the first visible light, the second visible light, and the third visible light are different from each other,
in one pixel, a virtual graphic of lines connecting centers of the first light-emitting unit, the second light-emitting unit, the third light-emitting unit, and the photosensitive unit is a polygon; and
in a first direction parallel to the substrate, the second light-emitting unit is shared by two adjacent pixels, or the third light-emitting unit is shared by the two adjacent pixels;
in the first direction parallel to the substrate, centers of the second light-emitting unit, the third light-emitting unit, and the photosensitive units of the two adjacent pixels are located on a straight line;
in a second direction parallel to the substrate, centers of the first light-emitting units and the photosensitive units of the two adjacent pixels are located on a straight line, and an angel between the first direction and the second direction is greater than 0 degrees;
the first direction is perpendicular to the second direction;
the plurality of pixels are divided into a plurality of row pixel groups in the second direction, and when the n-th row pixel group of the plurality of row pixel groups is configured to display, the (n-m)-th row pixel group of the plurality of row pixel groups is configured not to display; and
a value of m is 1 or 2.

11. A display module, comprising:
a display panel, comprising a plurality of pixels, at least part of the plurality of pixels comprising a photosensitive unit and a plurality of light-emitting units, the plurality of light-emitting units comprising a first light-emitting unit, the first light-emitting unit configured to emit at least a first visible light, and the photosensitive unit configured to detect the first visible light; and
a light guiding layer provided above the plurality of pixels, comprising a plurality of light guiding structures, the first visible light emitted by the first light-emitting unit being received by a corresponding photosensitive unit through a corresponding light guiding structure;
wherein in one pixel, the first light-emitting unit has a first center line, the first center line is a straight line passing through a center of the first light-emitting unit in a vertical direction, the photosensitive unit has a second center line, the second center line is a straight line passing through a center of the photosensitive unit in the vertical direction, the light guiding structure corresponding to the photosensitive unit has a third center line, the third center line is a straight line passing through a center of the light guiding structure corresponding to the photosensitive unit in the vertical direction, a first shortest distance is a shortest distance between the second center line and the first center line, a second shortest distance is a shortest distance between the third center line and the first center line, and the first shortest distance is greater than the second shortest distance.

12. The display module according to claim 11, wherein
the plurality of pixels comprise two adjacent pixels, the two adjacent pixels comprise a first pixel and a second pixel, among the two adjacent pixels, a first light-emitting unit of the first pixel has the first center line, a photosensitive unit of the first pixel has the second center line, and a light guiding structure corresponding to the photosensitive unit of the first pixel has the third center line, a first light-emitting unit of the second pixel has a fourth center line, the fourth center line is a straight line passing through a center of the first light-emitting unit of the second pixel in the vertical direction,
a third shortest distance is a shortest distance between the third center line and the fourth center line, and the second shortest distance is less than the third shortest distance.

13. The display module according to claim 11, wherein the display module is provided with a light-emitting surface, the photosensitive unit and the first light-emitting unit are provided in a same layer, and at least two angles between the first visible light detected by the photosensitive unit and the first center line are configured with a minimum angle and a maximum angle,
in one pixel, on a cross-section passing through the first center line and the second center line, a width of the first light-emitting unit is configured as a first dimension, a distance between the first light-emitting unit and the photosensitive unit is configured as a second dimension, a width of the photosensitive unit is configured as a third dimension, and a shortest distance between the first light-emitting unit and the light-emitting surface is configured as a fourth dimension;
a ratio of one half of the second dimension to the fourth dimension is configured as a first ratio, and a ratio of one half of the sum of the first dimension, the second dimension and the third dimension to the fourth dimension is configured as a second ratio, the minimum angle is greater than or equal to an arctangent value of the first ratio, and the maximum angle is greater than or equal to an arctangent value of the second ratio;
the minimum angle is 0 degrees, and the maximum angle is 10 degrees.

14. The display module according to claim 11, wherein in one pixel,
on a cross-section passing through the first center line and the second center line, the photosensitive unit has a first edge close to the first light-emitting unit, the light guiding structure corresponding to the photosensitive unit has a second edge located between the first center line and the third center line, a shortest distance between the first edge and the first center line is greater than a shortest distance between the second edge and the first center line;
an angle between the first visible light detected by the photosensitive unit and the first center line is configured with a minimum angle, and an angle between a line connecting the first edge and the second edge and the first center line is greater than or equal to the minimum angle;
the minimum angle is 0 degrees;
in one pixel, on the cross-section passing through the first center line and the second center line, the photosensitive unit has a third edge away from the first center line, the light guiding structure corresponding to the photosensitive unit has a fourth edge away from the first center line, and a shortest distance between the third edge and the first center line is greater than a shortest distance between the fourth edge and the first center line;
the angle between the first visible light detected by the photosensitive unit and the first center line is configured with a maximum angle, and an angle between a line connecting the third edge and the fourth edge and the first center line is greater than or equal to the maximum angle;
the maximum angle is 10 degrees;
the display panel further comprises a substrate, the plurality of pixels are disposed on the substrate, and part of an orthographic projection of the light guiding structure on the substrate is located outside an orthographic projection of the photosensitive unit on the substrate; and
the angle between the first visible light detected by the photosensitive unit and the first center line is greater than or equal to 0 degree and less than or equal to 10 degrees.

15. The display module according to claim 11, the light guiding structure comprising:
a first light transmitting unit provided above the corresponding pixel, wherein the first light transmitting unit has a first refractive index and comprises a first groove concaved toward the corresponding pixel; and
a second light transmitting unit filled in the first groove, wherein the second light transmitting unit has a second refractive index, and the second refractive index is greater than the first refractive index;
on a cross-section passing through the first center line and the second center line, a cross-sectional shape of the second light transmitting unit filled in the first groove is arched;
the first light transmitting unit and the second light transmitting unit have an interface, and on the cross-section passing through the first center line and the second center line, the interface between the first center line and the third center line has a first curvature, the interface between the second center line and the third center line has a second curvature, and the first curvature is not equal to the second curvature;
the first curvature is less than the second curvature.

16. The display module according to claim 11, the light guiding layer further comprising:
a light absorbing structure provided with a plurality of first openings, each of the plurality of light guiding structures being located within the corresponding first opening; wherein
the display panel further comprises a substrate, the plurality of pixels are disposed on the substrate, the light absorbing structure is further provided with a plurality of second openings, and the light guiding layer further comprises:
a plurality of first color resistance structures, each of the plurality of first color resistance structures is located within the corresponding second opening; and
an orthographic projection of each first light-emitting unit on the substrate is located within an orthographic projection of the corresponding first color resistance structure on the substrate, or the orthographic projection of each first light-emitting unit on the substrate coincides with the orthographic projection of the corresponding first color resistance structure on the substrate;
part of an orthographic projection of the photosensitive unit on the substrate is located within an orthographic projection of the light absorbing structure on the substrate;
a material of the light guiding structure is a transparent material;
the light guiding structure is a color resistance, and the light guiding structure has a same color as the first color resistance structure;
colors of the first visible light, the light guiding structure, and the first color resistance structure are green;
the light absorbing structure is a black color resistance;
the light guiding layer is multiplexed as a color film layer;
an angle between the first visible light detected by the photosensitive unit and the first center line is configured with a minimum angle, wherein
on the cross-section passing through the first center line and the second center line, an inner wall, located between the first center line and the third center line, of the first opening is configured to be a first inner wall; a first angle is an angle between the first inner wall and the first center line, and the first angle is greater than or equal to the minimum angle;
on the cross-section passing through the first center line and the second center line, an inner wall, located between the second center line and the third center line, of the first opening is configured to be a second inner wall, a second angle is an angle between the second inner wall and the second center line, and the second angle is greater than or equal to the first angle.

17. The display module according to claim 11, the light guiding layer further comprising:
a light absorbing structure provided with a plurality of first openings, each of the plurality of light guiding structures being located within the corresponding first opening; and
a plurality of lens structures disposed with intervals, each of the plurality of lens structures being located on a side, away from the display panel, of the corresponding light guiding structure; wherein
each of the plurality of lens structures comprises:
a first light transmitting unit located on a side, away from the display panel, of the corresponding light guiding structure, the first light transmitting unit having a first refractive index and comprising a first groove concaved toward the corresponding light guiding structure; and
a second light transmitting unit filled the first groove, the second light transmitting unit having a second refractive index, and the second refractive index being greater than the first refractive index.

18. The display module according to claim 11, wherein the display panel further comprises a substrate, the plurality of pixels are disposed on the substrate, the plurality of light-emitting units further comprise a second light-emitting unit and a third light-emitting unit, the second light-emitting unit is configured to emit at least a second visible light, the third light-emitting unit is configured to emit at least a third visible light, and colors of the first visible light, the second visible light, and the third visible light are different from each other,
in one pixel, a virtual graphic of lines connecting centers of the first light-emitting unit, the second light-emitting unit, the third light-emitting unit, and the photosensitive unit is a polygon; and
in a first direction parallel to the substrate, the second light-emitting unit is shared by two adjacent pixels, or the third light-emitting unit is shared by the two adjacent pixels;
in the first direction parallel to the substrate, centers of the second light-emitting unit, the third light-emitting unit, and the photosensitive units of the two adjacent pixels are located on a straight line;
in a second direction parallel to the substrate, centers of the first light-emitting units and the photosensitive units of the two adjacent pixels are located on a straight line, and an angel between the first direction and the second direction is greater than 0 degrees;
the first direction is perpendicular to the second direction;
the plurality of pixels are divided into a plurality of row pixel groups in the second direction, and when the n-th row pixel group of the plurality of row pixel groups is configured to display, the (n-m)-th row pixel group of the plurality of row pixel groups is configured not to display;
a value of m is 1 or 2.

19. A display device, comprising:
a display panel according to claim 1.

20. A display device, comprising:
a display module according to claim 11.
